(19) United States
(12) Patent Application Publication
(10) Pub. No.: US 2026/0323815 A1
(43) Pub. Date: Oct. 15, 2026

(54) SUBSTRATE STRUCTURE AND MANUFACTURING METHOD THEREOF

(71) Applicant: Unimicron Technology Corp., Taoyuan City (TW)

(72) Inventors: Chin-Sheng Wang, Taoyuan City (TW); Ra-Min Tain, Hsinchu County (TW); Chia-Fu Hsu, Taichung City (TW); Shih-Lian Cheng, New Taipei City (TW)

(73) Assignee: Unimicron Technology Corp., Taoyuan City (TW)

(21) Appl. No.: 19/287,836

(22) Filed: Aug. 1, 2025

Related U.S. Application Data
(60) Provisional application No. 63/789,405, filed on Apr. 15, 2025.

(30) Foreign Application Priority Data
Jul. 14, 2025 (TW) 114126504

(51) Int. Cl. H05K 1/02; H05K 1/03; H05K 1/09; H05K 3/46

(52) U.S. Cl. CPC H05K 1/0271; H05K 1/0277; H05K 1/0306; H05K 1/09; H05K 3/4605; H05K 2201/0112

(57) ABSTRACT

A substrate structure includes a core layer, an insulating layer, and a through-conductive element. The core layer includes a first surface, a second surface, and a through hole. The first surface and the through hole have a first corner at a junction thereof. The second surface and the through hole have a second corner at a junction thereof. A material of the core layer has a first Young's modulus. The insulating layer includes a first insulating portion and a second insulating portion that are separated and located at the first corner and the second corner respectively. A material of the insulating layer has a second Young's modulus, and the second Young's modulus is smaller than the first Young's modulus. The through-conductive element is disposed on the insulating layer and in the through hole. A manufacturing method of a substrate structure is also provided.

### CROSS-REFERENCE TO RELATED APPLICATION

This application claims the priority benefits of U.S. provisional application serial no. 63/789,405, filed on Apr. 15, 2025, and Taiwan application serial no. 114126504, filed on Jul. 14, 2025. The entirety of each of the above-mentioned patent applications is hereby incorporated by reference herein and made a part of this specification.

### BACKGROUND

### Technical Field

The disclosure relates to a substrate structure and a manufacturing method thereof.

### Related Art

In the manufacturing process of substrates, typically a base is used as the core, and conductive vias are formed to connect circuit layers on opposite surfaces of the base. However, stress concentration phenomena often occur during the formation of these components, which significantly affects product reliability.

### SUMMARY

The disclosure provides a substrate structure and a manufacturing method thereof, which may effectively improve product reliability.

A substrate structure of the disclosure includes a core layer, an insulating layer, and a through-conductive element. The core layer includes a first surface, a second surface, and a through hole. The first surface and the through hole have a first corner at a junction thereof. The second surface and the through hole have a second corner at a junction thereof. A material of the core layer has a first Young's modulus. The insulating layer includes a first insulating portion and a second insulating portion that are separated and located at the first corner and the second corner, respectively. A material of the insulating layer has a second Young's modulus, and the second Young's modulus is smaller than the first Young's modulus. The through-conductive element is disposed on the insulating layer and in the through hole.

A manufacturing method of a substrate structure of the disclosure at least includes the following steps. A core layer including a first surface and a second surface opposite to each other and a through hole penetrating from the first surface to the second surface are provided, in which a material of the core layer has a first Young's modulus. An insulating layer is formed on the core layer, in which a first insulating portion of the insulating layer extends from the first surface into the through hole, a second insulating portion of the insulating layer extends from the second surface into the through hole, a material of the insulating layer has a second Young's modulus, and the second Young's modulus is smaller than the first Young's modulus. A through-conductive element is formed on the through hole and the insulating layer.

Based on the above, the substrate structure of the disclosure is designed based on the relative relationship of Young's modulus between the core layer and the insulating layer, and the insulating layer is positioned corresponding to the corner of the core layer, which can effectively alleviate the stress generated at the corner of the core layer during the manufacturing process, thereby effectively improving product reliability.

To make the foregoing features and advantages of the disclosure more comprehensible, the following specifically presents embodiments and provides detailed descriptions together with the accompanying drawings as follows.

### BRIEF DESCRIPTION OF THE DRAWINGS

FIGS. 1A-1E are cross-sectional schematic diagrams of a manufacturing method of a substrate structure according to an embodiment of the disclosure.

FIGS. 2-3 are cross-sectional schematic diagrams of substrate structures according to some embodiments of the disclosure.

### DESCRIPTION OF THE EMBODIMENTS

In the following detailed description, for purposes of explanation and not limitation, exemplary embodiments disclosing specific details are set forth to provide a thorough understanding of various principles of the disclosure. However, it will be apparent to persons of ordinary skill in the art that, with the benefit of this disclosure, the disclosure may be practiced in other embodiments that depart from the specific details disclosed herein. Furthermore, descriptions of well-known devices, methods, and materials may be omitted so as not to obscure the description of various principles of the disclosure.

The disclosure is more fully illustrated with reference to the drawings of this embodiment. However, the disclosure may also be embodied in various different forms and should not be limited to the embodiments described herein. The thickness, dimensions, or size of layers or regions in the drawings may be exaggerated for clarity. The same or similar reference numbers indicate the same or similar components, and the following paragraphs will not describe them repeatedly.

The aforementioned and other technical content, features, and effects of the disclosure will be clearly presented in the following detailed description of various embodiments with reference to the drawings. The directional terms mentioned in the following embodiments, such as "upper," "lower," "top," "bottom," "left," "right," are merely references to the directions of the accompanying drawings. Therefore, the directional terms used are for illustration and are not intended to limit the disclosure.

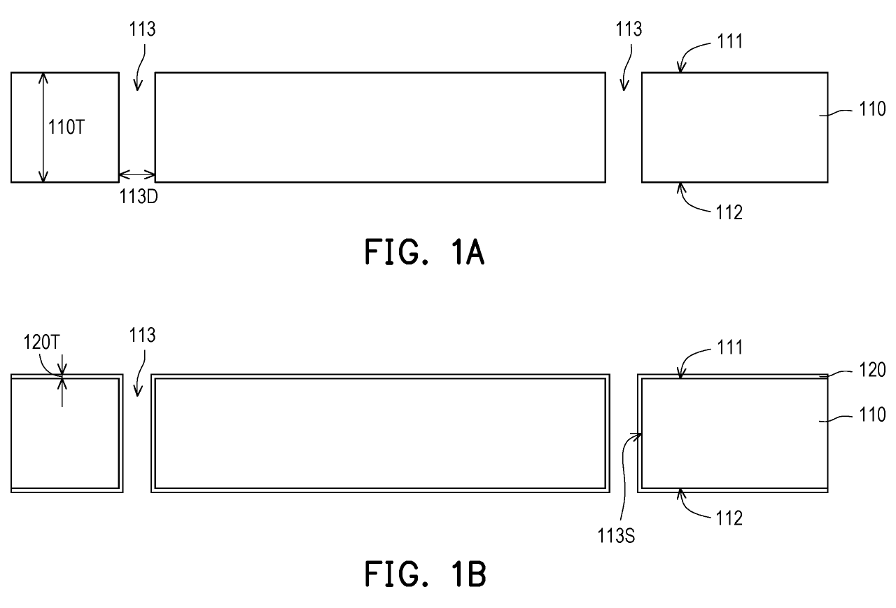

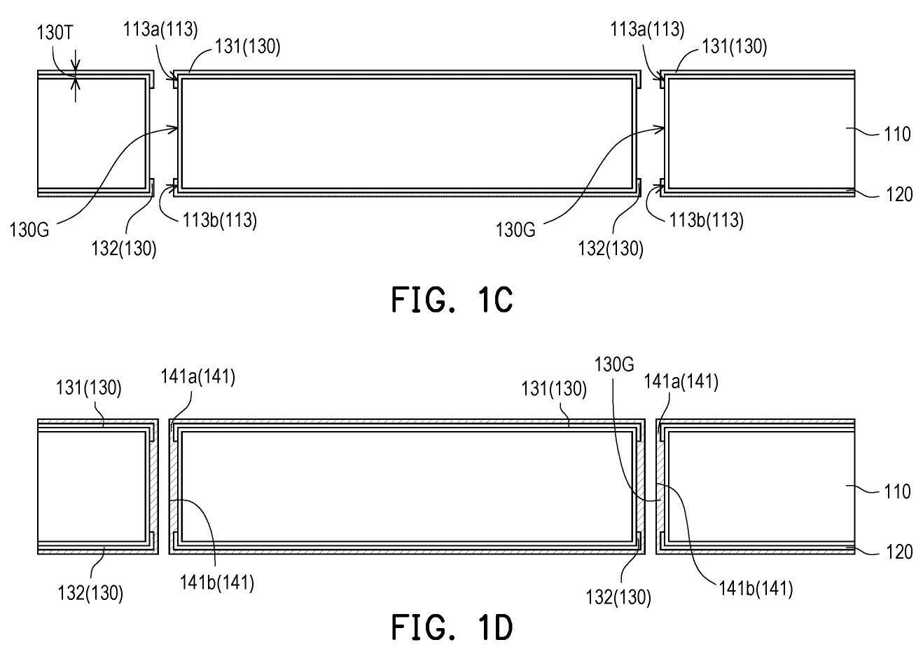

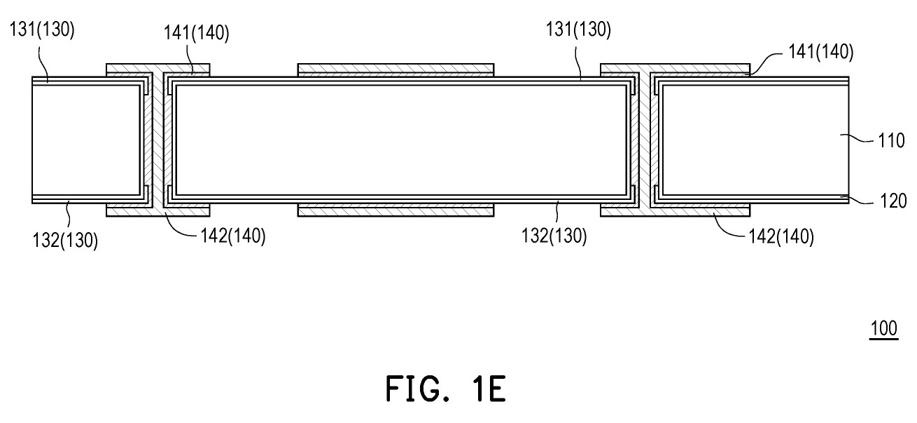

In this embodiment, the manufacturing process of the substrate structure may include the following steps. Referring to FIG. 1A, first, a core layer 110 is provided, in which the core layer 110 has a first surface 111 and a second surface 112 (for example, the upper surface and lower surface in FIG. 1A) opposite to each other, and a plurality of through holes 113 (two through holes 113 are schematically illustrated) penetrating from the first surface 111 to the second surface 112. In one embodiment, the core layer 110 is, for example, an insulating substrate. In one embodiment, the insulating substrate may be, for example, an inorganic substrate, and the material of the inorganic substrate is, for example, glass or ceramic. That is, when the material of the core layer 110 is glass, the through holes 113 may be through glass vias (TGV), and when the material of the core layer 110 is ceramic, the through holes 113 may be through ceramic vias (TCV), but the disclosure is not limited thereto. In one embodiment, the surface roughness (for example, Sa) of the first surface 111 and the second surface 112 is less than 15 nano or any other suitable value, in which Sa is an extension of Ra (arithmetic mean height of lines) to the surface, which expresses in absolute value the difference of the height of each point compared to the arithmetic mean value of the surface, and this parameter is generally used to evaluate surface roughness. In one embodiment, a thickness 110T of the core layer 110 is, for example, in a range of 50 micrometers to 1000 micrometers or any other suitable range. In one embodiment, a diameter 113D of the through holes 113 is, for example, in a range of 10 micrometers to 200 micrometers or any other suitable range.

Referring to FIG. 1B, a promotion layer 120 is conformally formed on the core layer 110, such that the first surface 111, the second surface 112, and an inner wall 113S of the through holes 113 are all covered by the promotion layer 120. In other words, the first surface 111, the second surface 112, and the inner wall 113S of the through holes 113 are all not exposed. In one embodiment, the material of the promotion layer 120 is, for example, oxide or nitride, in which the oxide is, for example, titanium oxide (TiO_{X}) (such as titanium monoxide (TiO) or titanium dioxide (TiO₂)), silicon oxide (SiO_{X}) (such as silicon dioxide (SiO₂)), or aluminum oxide (Al₂O₃), and the nitride is, for example, silicon nitride (SiN_{X}) (such as silicon nitride (Si₃N₄)). In this embodiment, the promotion layer 120 is a dense film layer formed through atomic layer deposition (ALD), evaporation process, or the like, with a thickness 120T of, for example, in a range of 0.01 nano to 100 nano, therefore it may increase the adhesion between the core layer 110 and the film layer subsequently formed thereon.

Referring to FIG. 1C, an insulating layer 130 is formed on the core layer 110, in which a first insulating portion 131 of the insulating layer 130 extends from the first surface 111 into the through hole 113, and a second insulating portion 132 of the insulating layer 130 extends from the second surface 112 into the through hole 113. In this way, the insulating layer 130 may include the first insulating portion 131 and the second insulating portion 132 that are separated and located at the first corner 113a and the second corner 113b of the through hole 113 respectively. In addition, the Young's modulus of the insulating layer 130 is smaller than the Young's modulus of the core layer 110. Accordingly, the substrate structure of this embodiment (such as a substrate structure 100 in FIG. 1E) is designed through the relative relationship of Young's modulus between the core layer 110 and the insulating layer 130, and the insulating layer 130 corresponds to the corner of the core layer 110. In this way, stress generated at the corner of the core layer 110 during the manufacturing process (such as high-temperature process,) may be effectively alleviated, thereby effectively improving product reliability (such as performance and stability). For example, the first corner 113a is the junction between the first surface 111 and the through hole 113, and the second corner 113b is the junction between the second surface 112 and the through hole 113. When the material of the core layer 110 is glass, without forming the insulating layer 130, it will directly contact with subsequent circuits, so stress concentrates at the edge of the through hole 113 (such as the turning point between the hole wall and the surface), which easily causes cracks in the glass and adversely affects product reliability. In this embodiment, the insulating layer 130 with low Young's modulus is formed at the position where stress easily concentrates to reduce stress concentration phenomena at the edge of the through hole 113. Furthermore, the first insulating portion 131 and the second insulating portion 132 of this embodiment do not directly contact in the through hole 113, and a gap 130G is formed together when forming the insulating layer 130. In this way, the material of the insulating layer 130 may not be limited by the predicament that some materials cannot effectively fill the inner wall 113S at high aspect ratios, thereby significantly reducing process difficulty and improving material selection flexibility. Furthermore, the gap 130G of this embodiment is formed together by the promotion layer 120, the first insulating portion 131, and the second insulating portion 132, so a portion of a surface of the promotion layer 120 is exposed by the first insulating portion 131 and the second insulating portion 132.

In one embodiment, the insulating layer 130 may be formed through a suitable process (such as sputtering process) different from the promotion layer 120, and the material of the insulating layer 130 is different from the material of the promotion layer 120. For example, the material of the insulating layer 130 includes organic material, inorganic material, or combinations thereof, such as the material of the insulating layer 130 includes photoimageable dielectric material (PID) or the like. In one embodiment, the Young's modulus of the promotion layer 120 is greater than the Young's modulus of the insulating layer 130. In one embodiment, a thickness 130T of the insulating layer 130 is greater than the thickness 120T of the promotion layer 120, and the thickness 130T of the insulating layer 130 is, for example, in a range of 0.1 micrometers to 20 micrometers, but the disclosure is not limited thereto, and the thickness 130T of the insulating layer 130 may also be equal to the thickness 120T of the promotion layer 120.

Referring to FIGS. 1D-1E, a through-conductive element 140 is formed on the insulating layer 130 and filled into the through hole 113, therefore the through-conductive element 140 directly contacts the promotion layer 120, in which the through-conductive element 140 may include a metal layer 141 and a conductive layer 142, and may be manufactured in the following manner. Furthermore, as shown in FIG. 1D, the metal layer 141 may fill the gap 130G between the first insulating portion 131 and the second insulating portion 132 through a sputtering process, such that the metal layer 141 has a first metal part 141a and a second metal part 141b in the through hole 113, and the width of the first metal part 141a is different from the width of the second metal part 141b, such as the width of the second metal part 141b is greater than the width of the first metal part 141a. In one embodiment, the metal layer 141 may be called a seed layer to improve the adhesion between the conductive layer 142 and other film layers. In one embodiment, the material of the metal layer 141 includes titanium-copper alloy, electroless plated metal, or a combination thereof, in which the electroless plated metal may be formed by an electroless plating process, and the material includes nickel-phosphorus, copper, silver, or combinations of the above materials. In one embodiment, the thickness of the metal layer 141 is, for example, less than 1 micrometer. Next, as shown in FIG. 1E, the conductive layer 142 is formed on the metal layer 141 and filled into the through hole 113, then a patterning process is performed to remove portions of the metal layer 141 and the conductive layer 142, in which the metal layer 141 and the conductive layer 142 may together be regarded as the through-conductive element 140. In the present embodiment, the conductive layer 142 fills the through hole 113, but the disclosure is not limited thereto. In an embodiment not shown, the conductive layer 142 does not completely fill the through hole 113. In one embodiment, the Young's modulus of the conductive layer 142 is greater than the Young's modulus of the insulating layer 130. Through the above manufacturing process, the substrate structure 100 of the present embodiment is substantially completed.

It should be explained here that the following embodiments use the reference numerals and partial content of the above embodiments, in which the same or similar reference numerals are used to represent the same or similar components, and the explanation of the same technical content is omitted. For the explanation of the omitted parts, reference may be made to the foregoing embodiments, so details will not be repeated in the following embodiments.

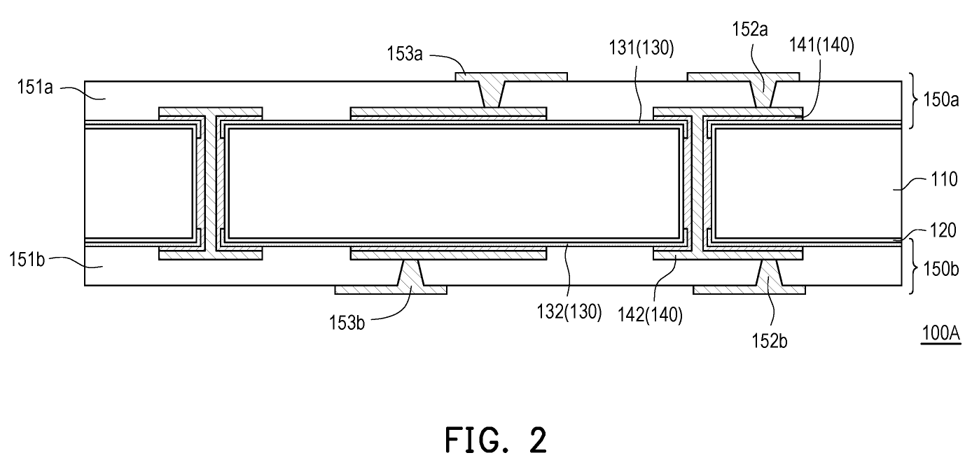

Please refer to FIG. 2, which is similar to FIG. 1E, while the difference is that, in a substrate structure 100A of this embodiment, after forming the through-conductive element 140, at least one buildup structure electrically connected to the through-conductive element 140 is formed (illustratively illustrating a first buildup structure 150a and a second buildup structure 150b) on at least one of the first surface 111 and the second surface 112 of the core layer 110 (illustratively formed on the first surface 111 and the second surface 112 respectively). The first buildup structure 150a includes at least one dielectric layer (illustratively illustrating one dielectric layer 151a), at least one conductive via (illustratively illustrating two conductive vias 152a), and at least one circuit (illustratively illustrating two circuits 153a). The dielectric layer 151a is located on the first insulating portion 131 of the insulating layer 130, the circuit 153a is located on the dielectric layer 151a, and the conductive via 152a is located within the dielectric layer 151a and electrically connects the circuit 153a and the through-conductive element 140. Similarly, the buildup structure 150b includes at least one dielectric layer (illustratively illustrating one dielectric layer 151b), at least one conductive via (illustratively illustrating two conductive vias 152b), and at least one circuit (illustratively illustrating two circuits 153b). The dielectric layer 151b is located on the second insulating portion 132 of the insulating layer 130, the circuit 153b is located on the dielectric layer 151b, and the conductive via 152b is located within the dielectric layer 151b and electrically connects the circuit 153b and the through-conductive element 140. Through the configuration of the buildup structures 150a, 150b, a fan-out structure may be formed, thereby increasing the applicability of the substrate structure 100A.

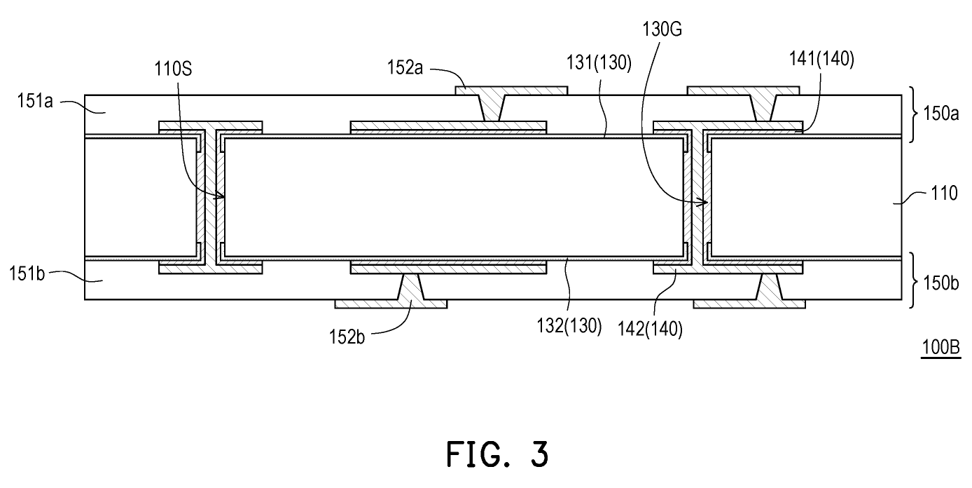

Please refer to FIG. 3, which is similar to FIG. 2, while the difference is that, the through-conductive element 140 of the substrate structure 100B of this embodiment directly contacts the core layer 110, that is, the adhesion layer 120 is further omitted in this embodiment. Furthermore, the gap 130G of this embodiment is formed together by the core layer 110, the first insulating portion 131, and the second insulating portion 132, therefore part of an inner wall 110S of the core layer 110 is exposed by the first insulating portion 131 and the second insulating portion 132.

In summary, the substrate structure of the disclosure is designed based on the relative relationship of Young's modulus between the core layer and the insulating layer, and the insulating layer is positioned corresponding to the corner of the core layer, which can effectively alleviate the stress generated at the corner of the core layer during the manufacturing process, thereby effectively improving product reliability.

Although the disclosure has been disclosed above with embodiments, the embodiments are not intended to limit the disclosure. Persons having ordinary knowledge in the technical field may make slight changes and modifications without departing from the spirit and scope of the disclosure. Therefore, the protection scope of the disclosure shall be defined by the appended claims.

What is claimed is:

1. A substrate structure, comprising:
a core layer comprising a first surface and a second surface opposite to each other and a through hole penetrating from the first surface to the second surface, wherein the first surface and the through hole have a first corner at a junction thereof, the second surface and the through hole have a second corner at a junction thereof, and a material of the core layer has a first Young's modulus;
an insulating layer comprising a first insulating portion and a second insulating portion that are separated and located at the first corner and the second corner respectively, wherein a material of the insulating layer has a second Young's modulus, and the second Young's modulus is smaller than the first Young's modulus; and
a through-conductive element disposed on the insulating layer and in the through hole.

2. The substrate structure as claimed in claim 1, wherein the first insulating portion and the second insulating portion do not directly contact in the through hole.

3. The substrate structure as claimed in claim 1, wherein the material of the insulating layer comprises photoimageable dielectric material.

4. The substrate structure as claimed in claim 1, wherein the material of the core layer comprises glass or ceramic.

5. The substrate structure as claimed in claim 1, wherein a surface roughness of the first surface and the second surface is less than 15 nano.

6. The substrate structure as claimed in claim 1, wherein a diameter of the through hole is in a range of 10 micrometers to 200 micrometers.

7. The substrate structure as claimed in claim 1, wherein the through-conductive element comprises a metal layer, the metal layer is configured on the insulating layer and fills between the first insulating portion and the second insulating portion.

8. The substrate structure as claimed in claim 7, wherein the metal layer has a first metal part and a second metal part in the through hole, and a width of the first metal part is different from a width of the second metal part.

9. The substrate structure as claimed in claim 7, wherein a material of the metal layer comprises sputtered titanium-copper alloy, electroless plated metal, or a combination thereof.

10. The substrate structure as claimed in claim 1, further comprising a promotion layer covering the first surface, the second surface, and an inner wall of the through hole.

11. The substrate structure as claimed in claim 10, wherein a gap is formed between the promotion layer, the first insulating portion, and the second insulating portion.

12. The substrate structure as claimed in claim 10, wherein the through-conductive element directly contacts the promotion layer.

13. The substrate structure as claimed in claim 10, wherein the material of the insulating layer is different from a material of the promotion layer.

14. The substrate structure as claimed in claim 13, wherein the material of the promotion layer comprises oxide or nitride.

15. The substrate structure as claimed in claim 10, wherein a thickness of the promotion layer in a range of 0.01 nano to 100 nano.

16. The substrate structure as claimed in claim 1, wherein the insulating layer directly contacts the core layer.

17. A manufacturing method of a substrate structure, comprising:
providing a core layer comprising a first surface and a second surface opposite to each other and a through hole penetrating from the first surface to the second surface, wherein a material of the core layer has a first Young's modulus;
forming an insulating layer on the core layer, wherein a first insulating portion of the insulating layer extends from the first surface into the through hole, a second insulating portion of the insulating layer extends from the second surface into the through hole, a material of the insulating layer has a second Young's modulus, and the second Young's modulus is smaller than the first Young's modulus; and
forming a through-conductive element on the through hole and the insulating layer.

18. The manufacturing method of the substrate structure as claimed in claim 17, wherein a gap between the first insulating portion and the second insulating portion is formed together when forming the insulating layer.

19. The manufacturing method of the substrate structure as claimed in claim 17, wherein before forming the insulating layer, further comprising conformally forming a promotion layer on the core layer, such that the first surface, the second surface, and an inner wall of the through hole are all covered by the promotion layer.

20. The manufacturing method of the substrate structure as claimed in claim 19, wherein a portion of a surface of the promotion layer is exposed by the first insulating portion and the second insulating portion.
